(19) United States
(12) Patent Application Publication
(10) Pub. No.: US 2025/0167017 A1
(43) Pub. Date: May 22, 2025

(54) MULTI-CHAMBER ASSEMBLY FOR HANDLING REMOVABLE EPITAXIAL REACTION UNITS

(71) Applicant: LPE S.p.A., Milan (IT)

(72) Inventor: Maurilio Meschia, Asti (IT)

(21) Appl. No.: 18/954,085

(22) Filed: Nov. 20, 2024

(30) Foreign Application Priority Data
Nov. 21, 2023 (IT) 102023000024663
Apr. 30, 2024 (IT) 10202400009712

(51) Int. Cl. H01L 21/67; H01L 21/673; H01L 21/677

(52) U.S. Cl. CPC H01L 21/67167; H01L 21/67109; H01L 21/6719; H01L 21/67196; H01L 21/67389; H01L 21/67766

(57) ABSTRACT

The present invention relates to a multi-chamber assembly for the handling and storage of removable reaction units for preventive maintenance operations, where said reaction units are used in reactors for the epitaxial deposition of semiconductor films on substrates. The present invention further relates to a reactor assembly integrating an epitaxial reactor for the deposition of semiconductor films on substrates, and the multi-chamber assembly hereinbefore described.

### CROSS-REFERENCE TO RELATED APPLICATION(S)

This Application claims priority to IT application Ser. No. 10/202,4000009712, filed Apr. 30, 2024 and IT App Plant Pat. No. 10,202,3000024663, filed Nov. 21, 2023, the entire contents of which are incorporated herein by reference.

### FIELD OF INVENTION

The present invention relates to the field of preventive maintenance operations of removable reaction units for the deposition of semiconductor films on a substrate in epitaxial reactors.

The present invention further relates to the field of multi-chamber assemblies for the handling and conditioning of removable reaction units during preventive maintenance operations, in particular when said reaction units are used in reactors for the epitaxial deposition of semiconductor films on substrates.

The present invention further relates to multi-chamber assemblies for the handling and conditioning of both removable reaction units and substrate holders used in epitaxial reactors.

### BACKGROUND OF THE DISCLOSURE

The epitaxial growth equipment for the semiconductor industry may comprise a reactor containing a reaction and deposition chamber where the chemical vapor deposition process occurs. As a result of this process, several parts of the chamber will be subject to undesired product build-up and will require cleaning or substitution after several deposition cycles, to avoid affecting the quality and performance of the epitaxial deposition.

As a result, the consumable parts within the reaction chamber, as well as the walls and pieces composing the reaction chamber itself, necessitate preventive maintenance (PM) operations, which entail periodically accessing the chamber for the removal, cleaning, or substitution of said chamber as well as its concerned parts and pieces.

These operations heavily impact on the downtime of the reactor and its throughput. This issue is particularly felt in hot wall reactors for the deposition of SiC, where maintenance operations may occur up to one or more times a week, and cause interruptions that may last several hours.

In general, the removal, clean-up, and substitution of the concerned parts of a reaction chamber is a time-consuming process mostly carried out by hand.

Overall, the process requires a complete cooling and purge of the reactor, its undesired exposure to air, and the concurrent presence of one or more operators.

In the best-case scenario, where the reaction chamber is of the removable type, it is possible to pull out the reaction chamber from the reactor in its entirety via mechanical means. In this type of system, however, the reaction unit, i.e., the confined enclosed space (or working area) where the epitaxial deposition process takes place, cannot be easily decoupled from the bulky reaction chamber and is therefore for most purposes to be considered integral to the reaction chamber, since it cannot be individually handled and displaced.

For example, the reaction chamber described in EP 1570107 and US2022411961 is formed via the assembly of several elements which create an inner enclosure, hosting a working area that cannot be removed from the rest of the other susceptive elements on its own and in one piece.

The removal process of an entire reaction chamber as hereinbefore described presents several disadvantages: the access to the chamber is not automated or automatable, it requires the implementation of specific and time consuming EHS procedures, the reactor is exposed to air, and the displacement (and handling) of the reaction chamber is cumbersome and requires manual intervention.

It is also noted that in some last generation reactors, the handling of substrate holders is performed in an automated fashion and allows the substrate holders to be displaced from/to the reactor to/from a third chamber, apt to condition the substrates before entering the chamber and allowing to minimize their exposure to air.

It is therefore desirable to devise a chamber assembly for the insertion and replacement processes of a reaction unit of a reaction chamber from the reactor to a suitable enclosed space for purging/conditioning operations, without exposing the reaction unit to air and speeding up PM operations.

It is furthermore desirable to provide an automated mechanical system configured to displace the reaction unit of a reaction chamber within the multi-chamber assembly to conduct specific handling, conditioning and/or purging operations, and reduce PM times. It is also desirable to provide a multi-chamber assembly adapted to cooperate, without interference, with the automated handling of a substrate holder, if present.

Finally, it is desirable to provide a reactor assembly integrated with the chamber assembly in a fully automated fashion, to further decrease PM downtimes, reduce EHS concerns, and offer a compact integrated solution.

### SUMMARY OF THE DISCLOSURE

It is an object of the present invention to overcome the disadvantages of the prior art. More specifically, it is an object of the present invention to provide a multi-chamber assembly for the handling of one or more removable reaction units of an epitaxial reactor for the deposition of a semiconductor film on a substrate and to preferably avoid its exposure to air.

It is a further object of the present invention to provide a multi-chamber assembly capable to execute the automated handling of both a removable reaction unit and a substrate holder.

It is an additional object of the present invention to provide a multi-chamber assembly adapted to be connected to a reactor suitable for the deposition of Si, SiC, and GaN films on semiconductor substrates having a reaction chamber equipped with a removable reaction unit.

It is a further object of the present invention to provide a multi-chamber assembly suitable to perform the automated handling of a reaction unit for preventive maintenance operations with reduced downtimes.

It is another object of the present invention to provide a reactor assembly integrated with the multi-chamber assembly, in order to handle a reaction unit and a substrate holder in fully automated fashion, while proving a compact, integrated solution.

The main objectives hereinbefore described are achieved through the invention recited in the appended claims, which constitute an integral part of the present description.

It is noted that the use of reference signs in the claims does not limit their scope. The sole purpose of reference signs is to make the claims easier to understand in reference to the drawings.

This summary is provided to introduce a selection of concepts in a simplified form. These concepts are further described in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE FIGURES

FIG. 1 provides a simplified sketch of a multi-chamber assembly according to an embodiment of the present invention.

FIG. 2 provides a simplified sketch of a multi-chamber assembly according to another embodiment of the present invention.

FIG. 3 provides a simplified sketch of a multi-chamber assembly according to another embodiment of the present invention.

It will be appreciated that elements in the figures are illustrated for simplicity and clarity and have not necessarily been drawn to scale. For example, the dimensions of some of the elements in the figures may have been omitted or, on the other hand, exaggerated relative to other elements to help improve understanding of illustrated embodiments of the present disclosure.

### DETAILED DESCRIPTION OF EXEMPLARY EMBODIMENTS

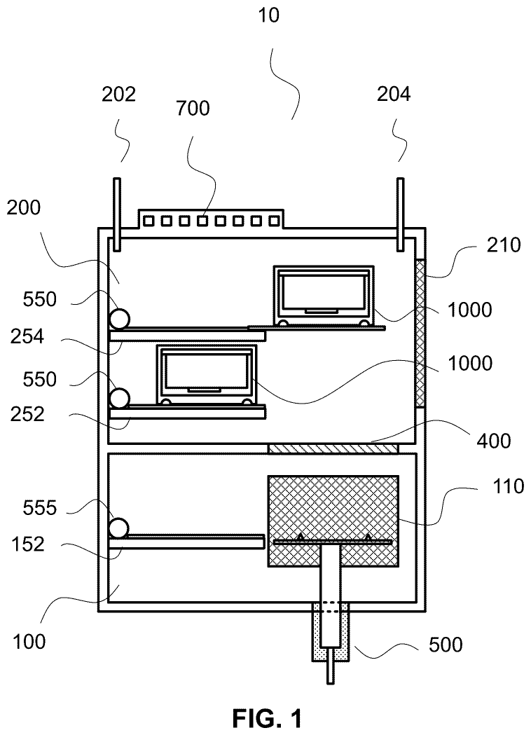

This application claims priority to IT application Ser. No. 10/202,4000009712, filed Apr. 30, 2024, the entire contents of which are incorporated herein by reference. In particular, but not exclusively, incorporation by reference is made in regard to: claims 1-14, FIGS. 1-3 and the corresponding sections of the description of IT application Ser. No. 10/202,4000009712.

This application also claims priority to IT application Ser. No. 10/202,3000024663, filed Nov. 21, 2023, the entire contents of which are incorporated herein by reference. In particular, but not exclusively, incorporation by reference is made in regard to: claims 1-16, FIGS. 1-3 and the corresponding sections of the description of IT application Ser. No. 10/202,3000024663.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Epitaxial reactors such as those used in SiC deposition often comprise a reaction chamber formed by one or more structural elements assembled together to create at least one enclosure, which defines at least one inner space, or working area, where the actual deposition takes place. See for instance EP 1570107 and U.S. Pat. No. 20,224,11961.

During PM operations, the reaction chambers like the ones described in the above non limiting example, provided solely for illustrative purpose, usually do not allow to remove and handle the specific enclosure where the deposition occurs. The bulky reaction chamber either needs to be extracted in one piece or internally accessed to remove the individual parts affected by undesired build up.

The applicant has devised an alternative reaction chamber design, where the reaction and deposition processes take place within an enclosed workplace, i.e., a reaction unit of a removable kind, which can be extracted in one piece from an essentially hollow casing and is adapted to cooperate with automated handling machines, optionally provided with specifically designed end effectors.

Such reaction unit is therefore a removable component of the reaction chamber of a reactor for the epitaxial deposition of semiconductor films on a substrate. It will be identified hereinafter as “removable reaction unit” or “reaction unit”.

This novel design allows to extract and replace the reaction unit or its consumable parts in a simple manner, without having to reach its interiors from within the reactor machine or having to displace the entire, bulky, reaction chamber outside the reactor machine to access its internal parts and pieces, thus causing their undesired exposure to air.

The removable reaction unit of the reaction chamber may comprise engaging means, such as indentation, protrusions, hooks, loops, or slides, adapted to mechanically couple and cooperate with an end effector of a motorized mechanical system, or automated handling machine, in order to be handled in an automated fashion.

According to a first aspect, the present invention relates to a multi-chamber assembly for the handling of one or more removable reaction units of an epitaxial reactor for the deposition of a semiconductor film on a substrate.

The multi-chamber assembly comprises at least two chambers, a first chamber and a second chamber, as well as at least one transfer device setting the first chamber and the second chamber in communication with each other.

In particular, the first chamber, which can be also referred to as “transfer chamber”, comprises at least one opening adapted to transfer the reaction unit from/to the reaction chamber of the reactor. The first chamber may advantageously be connected to the reactor, either directly or via an enclosed space.

The opening may be advantageously closable, sealable, and/or lockable, to allow isolating the first chamber from the reactor, in particular to prevent leakage of gases and/or to withstand a differential pressure between the two. For example, the aperture may be provided with a gate valve. The first chamber may be optionally connected to a system for vacuum generation and to a system for flowing and discharging gases.

The second chamber is designed for storing and/or handling one or more removable reaction units for PM and extraction. It can be also referred to as “unit handling chamber”. It is provided with a resealable access suitable for the extraction and insertion of the reaction unit by an operator or by an automated system. After extraction, the removable reaction unit may be subject to routine PM operations, or it can be discarded at end of life.

The second chamber may be advantageously adapted to receive or discharge the removable reaction unit from/to the first chamber through a transfer device by means of a motorized mechanical system or a manually activate mechanical device.

Because of its storage capabilities, the second chamber allows to execute the replacement of a reaction unit for PM operations in a more efficient manner. The second chamber may be optionally conditioned, as will be discussed below, allowing to further prepare the reaction unit for PM or for entering the reactor for operation.

It can be inferred from the above that the term “chamber” indicates an enclosure surrounding a cavity and optionally provided with sealable apertures/openings.

The multi-chamber assembly described above allows to handle a removable reaction unit of an epitaxial reactor without exposing the latter to air. This allows to significantly reduce PM maintenance times.

Additionally, the multi-chamber assembly hereinbefore described may allow the automated handling of a reaction unit for preventive maintenance operations, thus positively impacting on the efficiency of the process.

It is understood that the reaction unit is a working area of the reactor suitable for the epitaxial deposition of a semiconductor film on a substrate. The substrate may be positioned on a substrate holder and lodged in a receiving area of the reaction unit. The substrate holder is a device that provides support to the substrate.

According to a preferred embodiment, the multi-chamber assembly according to the invention may include a motorized mechanical system comprising at least one inter-chamber actuator. The latter can be configured to grab and displace the removable reaction unit from the first chamber to the second chamber through the transfer device, and/or vice versa.

With the term “actuator” it is meant a part of a device or machine that allows it to achieve physical movements: it can be used to convert electrical, mechanical, gaseous, or hydraulic inputs into a linear or a rotatory movement, or to a sequential combination of both.

The above-described motorized mechanical system allows to move the reaction unit within the multi-chamber assembly without requiring the physical action or presence of an operator. Optionally, it can be remotely controlled with digital processing means, via cable or wireless, such as a computer.

In a non-limiting example, the motorized mechanical system may comprise a linear actuator provided with an end effector. The latter can be adapted to mechanically couple with the removable reaction unit to grab it and displace it, by moving from an extended position to a retreated position, and vice versa.

The end effector can be a gripper, such as: a rod, prong, fork, shovel, or combinations thereof.

To withstand the weight of the reaction unit, the end effector may be of a metallic or ceramic material, such as aluminum or silicon carbide (in oxide or nitride form), or titanium, stainless steel, and alloys thereof.

According to another embodiment, the transfer device comprises at least one transfer aperture, setting in communication the first chamber with the second chamber. It may further comprise one transfer gate valve adapted to open and close the transfer aperture. It is understood that the transfer aperture should be designed to allow the passage of the reaction unit alone and/or coupled to the motorized mechanical system, if present.

The first chamber and second chamber may be separated by a partition shared by both chambers, and the transfer aperture may be a through hole of suitable size formed on said partition.

Alternatively, the two chambers may not be integral with each other, but placed contiguous to each other (e.g., on top of each other, or side by side). In this case, the transfer aperture can be a through hole across two adjacent walls of the chambers, setting them in mutual direct communication.

In general, the first and second chamber may be placed one on top of the other, i.e., stacked in the vertical direction, regardless of the fact that they may be contiguous and/or integral to each other, or separated by other elements, as will be discussed below. This allows to reduce the footprint of the transfer device, and provides an advantageously compact solution.

According to a different embodiment, the transfer device comprises: (i) an interspace formed between the first chamber and second chamber; (ii) at least one first transfer aperture connecting the interspace with the first chamber; and (iii) at least one second transfer aperture connecting the interspace with the second chamber.

The term interspace hereby identifies and enclosed space separating the first chamber and the second chamber. In a non-limiting example, two walls of the enclosure may coincide with the walls of the first chamber and second chamber opposite to each other.

The first and second apertures face each other so that the removable reaction unit can be displaced between the first chamber and the second chamber passing though both the first and second aperture facing each other, and the portion of interspace between them.

The adjective “first” and “second” applied to the transfer apertures are meant to merely distinguish the apertures formed on the side facing the first chamber from the ones on the side facing the second chamber respectively, and do not imply any other limitation in their quantity, order, or position.

The transfer device additionally comprises at least one transfer gate valve adapted to seal the first and/or second transfer apertures.

Advantageously, each of the first apertures and each of the second apertures can be equipped with a gate valve, which are identified as first and second transfer gate valve respectively (thus depending on the side they are facing). The transfer device may comprise at least one automated double sealing system adapted to operate said first and said second transfer gate valves independently from each other.

This design prevents the second chamber and the first chamber from contaminating each other, especially if/when the two chambers are at a different pressure, and or are flushed with specific gaseous species. To this effect, it may be particularly advantageous to use a double valve system, comprising a first transfer gate valve and a second transfer gate valve individually closing/opening the first aperture and the second aperture, respectively.

According to an embodiment of the invention, the second chamber is provided with at least one shelf adapted to support one or more removable reaction units. The second chamber may further comprise a single-chamber automated system configured to displace at least one removable reaction unit within the second chamber, and optionally also through the resealable access. The resealable access connects the second chamber to the surrounding external area of the reactor. An operator may receive the reaction unit through the resealable access, to clean the unit or its consumable parts from parasitic deposits, or to dispose of the same.

The use of one or more shelves, preferably between 1 and 10, allows the second chamber to store multiple reaction units. For example, some shelves may be used to store reaction units due for PM, while others may store conditioned units, ready for use, to immediately replace the ones extracted for PM. To this effect, the shelves may be disposed at different heights depending on their purpose. Each shelf may store more than one reaction unit, preferably between 1 and 10.

The single-chamber automated system may comprise one or more actuators suitable to displace one or more reaction units within the second chamber to place it, or remove it, on/from the shelves. It may also allow to displace the reaction unit to/from each shelf and the outside of the multi-chamber assembly. Furthermore, these actuators may be advantageously adapted to collect the reaction unit form the motorized mechanical system when it enters the second chamber and position the reaction unit on a shelf.

In this way, the reaction unit may be transferred from a shelf of the second chamber to the first chamber, or vice versa. The first chamber may be also equipped with one or more shelves and can be provided with its own single-chamber automated systems, in analogy to the second chamber.

The actuators of the single-chamber automated system, regardless of the chamber where they are employed, may be optionally provided with end effectors suitable to mechanically couple with the reaction unit.

It is understood that each shelf and actuator may be integrated or integral to each other.

It is noted that the reaction unit may typically weight between 2-15 kg, preferably 2-10 kg, even more preferably 2.5-6 kg.

The reaction unit may exhibit an overall box-like shape with a rectangular cross section of 200-400 mm times 30-50 mm, and extending for 200-500 mm in a longitudinal direction.

The shelves shall be therefore configured to support a reaction unit having the size and weight described above.

Both the actuator of the single-chamber automated system and the inter-chamber actuator should be adapted to handle a reaction unit having the size and weight described above.

Both the actuator of the single-chamber automated system and the inter-chamber actuator may be designed to displace their targets in the horizonal plane (parallel to the floor supporting the transfer device) or in a vertical direction perpendicular to said horizontal plane, depending on the mutual arrangement of chambers and shelves.

Under an embodiment, the multi-chamber assembly according to the invention comprises a heating system configured to heat the second chamber to a temperature of 150-500° C. For example, the heating system may be an electrical resistance heating system.

The multi-chamber assembly may additionally comprise at least one vacuum system configured to create a vacuum of less than 10 mbar in the second chamber. The vacuum system may be also configured to create a vacuum of less than 1 mbar in the second chamber, or more preferably below 10⁻³ mbar.

The second chamber may be further provided with at least one gas inlet and at least one gas outlet. The inlet and outlet allow flushing the second chamber and the reaction units stored therein with suitable gases, such as purge gases. The gas inlet and outlet should be each connected to a suitable gas circuit.

The optional equipment of the second chamber here discussed, such as the heating system, the vacuum system and/or the gas/inlet and outlets, may be advantageously used to condition the reaction unit.

With the term “condition” it is meant a variety of operations, or cycles, suitable to prepare a reaction unit, or a part/device, before insertion in the reactor. Additionally, or alternatively, the conditioning operations or cycles can be adapted to make the reaction unit suitable to be accessed by an operator or machine and extracted from the assembly for the safe removal or cleaning of parts.

For instance, before removal of the reaction unit, it is possible to create a vacuum of less than 10 mbar inside the second chamber and to perform a refilling under an inert gas such as argon, nitrogen, helium, or xenon. In addition, or in alternative to the inert gas refilling, the reaction unit may undergo an inert gas purge, the inert gas of preference being argon.

An alternative conditioning cycle suited to be performed on a new/clean reaction unit before insertion in the reactor may comprise the steps of heating the second chamber to a temperature of 150-500° C. and perform a vacuum degassing (the vacuum in this case should preferably be below 1 mbar, even more preferably below 10⁻³ mbar).

According to yet another embodiment, the multi-chamber assembly according to the invention further comprises a third chamber placed in communication with the first chamber through a substrate transfer aperture.

The third chamber is adapted to receive or discharge the substrate holder from/to the first chamber through the substrate transfer aperture via motorized or manual means.

The first chamber may optionally comprise a gate valve adapted to seal the substrate transfer aperture. It may further include one or more substrate holder shelves.

The first chamber may further comprise a substrate holder opening adapted to receive the substrate holder from the reaction unit in the reactor, or vice versa. It may be equipped with one or more shelves and automated means to suitably handle and store the substrate holders.

It is understood that the substrate holders are devices adapted to hold one or more semiconductor substrates on which the epitaxial film deposition takes place.

The first chamber, the second chamber, and the third chamber may each be connected to a same or different vacuum system.

In particular, the third chamber may be a load lock chamber. It can be connected to a heating and/or cooling system and may be adapted to condition the substrates before use or prior to extraction. It is understood that the third chamber can be further provided with openings, gate valves, and optional automated systems for the handling of the substrate holders or substrates, and for sealing the third chamber as appropriate. The handling may include any displacement starting or abutting into the first chamber or third chamber, and/or reaching the inside of the reactor, and/or the external surrounding area of the multi-chamber assembly open to air.

The substrate handling automated systems may be equipped with end effectors adapted to mechanically couple with the substrate holders. These can be advantageously made of silicon carbide, borosilicate glass, sapphire glass, or quartz to avoid contamination of the substrate.

The multi-chamber assembly comprising the third chamber allows to handle both a substrate holder and a removable reaction unit of a reaction chamber, thereby providing a unique compact solution that is space effective. In case automated systems are used, the solution according to the invention does not require the presence of an operator in situ and/or manual intervention.

It is understood that in the embodiment described above, the handling of the substrate holder and of the reaction unit should be mutually arranged so as not to interfere with each other.

Under a second aspect, the present invention relates to a reactor assembly for displacing and handling a reaction unit for preventive reactor maintenance operations.

The reactor assembly features, without limitation: (i) a reactor for the epitaxial deposition of a semiconductor film on a substrate, comprising a reaction chamber having a reaction unit removable in one piece from a susceptive casing; (ii) a multi-chamber assembly according to any of the embodiments hereinbefore described; and (iii) an automated handling machine for handling a removable reaction unit.

The automated handling machine is provided with a selective handling assembly comprising a first end effector and a second end effector, respectively engaging with the removable reaction unit and a substrate holder so as not to interfere with each other.

Specifically, the first end effector is configured to mechanically couple with the removable reaction unit to displace it along a longitudinal direction (x); whereas the second end effector is adapted to mechanically couple with a substrate holder to displace it along the longitudinal direction.

For example, the first and/or second end effector can be a gripper, such as: a rod, prong, fork, shovel, or combinations thereof.

To withstand the weight of the reaction unit, the first end effector may be of a metallic or ceramic material, such as aluminum or silicon carbide, in oxide or nitride form, or titanium, stainless steel, and alloys thereof. The second end effector can be made of silicon carbide, borosilicate glass, sapphire glass, or quartz to avoid contamination of the substrate.

Furthermore, the selective handling assembly comprises at least a first actuator adapted to displace the first and second end effector in a longitudinal direction from an extended position to a retreated position, and vice versa.

The first end effector is designed to withdraw, or insert, the removable reaction unit from, or into, the reactor. Advantageously, the first actuator can displace the reaction unit between the reaction chamber in the reactor and the multi-chamber assembly, preferably in correspondence to the first chamber, and even more preferably to the reaction unit opening.

The second end effector is adapted to withdraw, or insert, the substrate holder from, or into, the removable reaction unit, especially when the reaction unit is positioned within the reactor chamber inside the reactor.

The presence of a reactor assembly, integrating a multi-chamber assembly and an epitaxial reactor, prevents the exposure of the reaction unit to air during its extraction and insertion from/into the reactor, and the presence of automated handling means provides for a completely automated process that may reduce the downtime of the reactor of up to 70%.

The reactor may be suitable for the epitaxial deposition of a semiconductor film, preferably Si, SiC or GaN, on a substrate. In a non-limiting example, it may be a hot wall, crossflow reactor.

The reactor may advantageously comprise a thermal insulation system, featuring one or more thermally insulating components, forming an enclosure to the reaction chamber. It may also include a liner suitable to direct process gases in the reaction unit and connected thereto with releasable coupling means.

The reactor may be protected by an outer enclosure, such a double wall quartz tube, allowing a cooling fluid to flow in the interspace between its two walls. Other elements, which are typically used in reactors such as those hereinbefore described, can and should be present, as it may be apparent to a person with average skill in the art.

One or more induction coils may be located outside the reactor in order to heat the susceptive casing or the reaction chamber and hence, directly or indirectly, the reaction unit enclosed therein.

### DESCRIPTION OF FIGURES

The illustrations presented herein are not meant to be actual views of any particular material, structure, or device, but are merely idealized representations that are used to describe embodiments of the disclosure. Specifically, they are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

FIG. 1 schematically illustrates an open view of an embodiment of the multi-chamber assembly (10) according to the invention. The multi-chamber assembly is suitable for the handling and storage of the removable deposition units (1000). The units are designed to be extracted in one piece from an epitaxial reactor for the deposition of a semiconductor film on a substrate.

The multi-chamber assembly comprises a first chamber (100), a second chamber (200), and a transfer device (400).

The first chamber features an opening (110), identifiable as a “transfer unit opening”, connected or connectable to the reactor. The opening may be equipped with a gate valve and is suited to receive/discharge a reaction unit from/to the reaction chamber of the reactor.

Connected to the first chamber is the transfer device (400), which in this case is integrated within the first chamber, and specifically in one of its walls. In the present embodiment, the transfer device is an aperture that sets the first chamber in communication with the second chamber. This aperture, which allows the displacement of a reaction unit between the first chamber and the second chamber, is therefore identified as a “transfer aperture”. It may be opened or closed with a gate valve (not shown), identified as a “transfer gate valve”.

The second chamber (200) is designed to store and condition the reaction units. It includes a resealable access (210) suitable for the extraction and insertion of the reaction unit by an operator or by an automated system.

The multi-chamber assembly is equipped with a motorized mechanical system (500) comprising one inter-chamber actuator adapted to grab and displace the removable reaction unit from the first chamber to the second chamber, and/or vice versa, through the transfer device.

The second chamber is provided with two shelves (252, 254) capable to support a reaction unit. A single-chamber automated system (550) is configured to displace the reaction unit within the second chamber, and specifically to grab it from the motorized mechanical system and place it on a shelf, or vice versa. The single-chamber automated system is also designed to displace the reaction unit in and out of the resealable access (210). This access sets the second chamber in communication with the outside environment. It allows an operator to subsequently handle the reaction unit for cleaning or disposal.

The single-chamber automated system (550) comprises two actuators, each coupled to one shelf.

The second chamber is equipped with a resistive heating system (700) configured to heat the second chamber to a temperature of 150-500° C. The second chamber also comprises an inlet (202) and outlet (204) for flowing selected gases. The second chamber is therefore suitable for conditioning of the reaction unit.

The first chamber is also equipped with one shelf (152) and a single-chamber automated system (555) configured to displace the reaction unit within the first chamber.

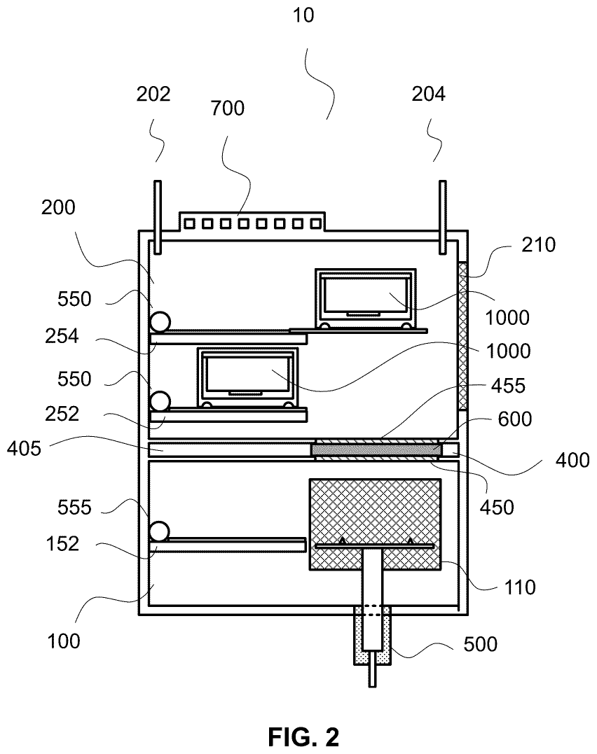

FIG. 2 schematically illustrates another embodiment of the multi-chamber assembly (10) according to the invention, adopting the same open view of FIG. 1, and using the same numerals for the same or equivalent functional features.

The present embodiment differs from the one described in FIG. 1 in that the transfer device (400) is an enclosure defining an interspace (405) placed between the first chamber and second chamber.

One “first transfer aperture” (450), i.e., an aperture opening towards the first chamber and suitable for transferring a reaction unit, connects the first chamber with the interspace.

One “second transfer aperture” (455), i.e., an aperture opening towards the second chamber and suitable for transferring a reaction unit, connects the interspace with the second chamber and faces directly the first transfer aperture. Since the first and second apertures face each other, it is possible to linearly displace the reaction unit through both apertures without difficulty.

The transfer device further comprises at least one transfer gate valve (600) adapted to seal the first and second transfer apertures. However, it is preferable to employ one gate valve per transfer aperture, and to operate them independently from each other.

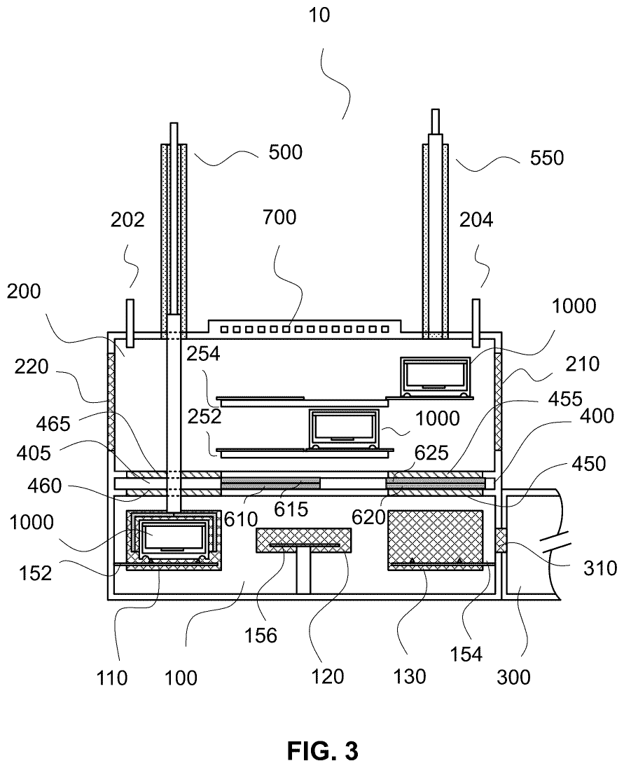

FIG. 3 schematically illustrates another embodiment of the multi-chamber assembly (10) according to the invention, adopting the same open view of FIG. 1 and FIG. 2, and using the same numerals for the same or equivalent functional features.

In the present embodiment, the multi-chamber assembly additionally comprises a third chamber (300) placed in communication with the first chamber (100) through a substrate transfer aperture (310), the latter being adapted to let through a substrate holder (and any automated means configured to displace said holder, if present).

The third chamber, here depicted only in part, is suitable for storing and optionally conditioning and/or cooling the substrates, before they enter the reactor, or after the deposition process.

Furthermore, the first chamber comprises two transfer unit openings (110, 130). These openings may be each equipped with a gate valve (not shown) and are suited to receive/discharge a reaction unit from/to the reaction chamber of the reactor. They can be connected or connectable to the epitaxial reactor.

The first chamber comprises a substrate holder opening (120), which is adapted to displace a substrate holder between the multi-chamber assembly and the reactor, or an additional enclosed area connected or connectable thereto.

The first chamber also includes two shelves 8152, 154) for supporting a reaction unit. It comprises an additional shelf, a substrate holder shelf (156), which allows to lay the substrate holder before transferring it to the reactor or to the third chamber.

In the present embodiment, the motorized mechanical system (500) comprises two linear inter-chamber actuators.

As a consequence, the transfer device (400) comprises an interspace (405) placed between the first chamber and second chamber, and two “first transfer apertures” (450, 460), connecting the interspace with the first chamber. It also includes two “second transfer apertures” (455, 465), connecting the interspace with the second chamber. The “first transfer apertures” (450, 460) face the “second transfer apertures” (455, 465).

In this instance, each of the first aperture and the second aperture may be respectively equipped with one “first transfer gate valve” (610, 620) and one “second transfer gate valve” (615, 625) to individually seal each transfer aperture independently from one another. To this effect, it is convenient to implement at least one automated double sealing system adapted to operate these first and second transfer gate valves independently from each other.

The subject matter of the present disclosure includes all novel and nonobvious combinations and sub-combinations of the various processes, systems, and configurations, and other features, functions, acts, and/or properties disclosed herein, as well as any and all equivalents thereof.

In the description and the claims in this application the words “comprise” and its variations such as “comprising” and “comprises” do not rule out the presence of other additional elements, components, or stages.

The discussion of documents, deeds, materials, apparatus, articles and the like is included in the text solely for the purpose of providing context for this invention; it should not however be understood that this material or part thereof constitutes general knowledge in the field relating to the invention prior to the priority date of each of the claims appended to this application.

1. A multi-chamber assembly for handling of at least one removable reaction unit of an epitaxial reactor comprising:
a first chamber comprising at least one opening adapted to receive or discharge the reaction unit from/to the epitaxial reactor;
a second chamber, for storing one or more removable reaction units, provided with a resealable access suitable for extraction and insertion of the reaction unit by an operator or by an automated system; and
a transfer device connecting the first chamber with the second chamber,
wherein the reaction unit is suitable for epitaxial deposition of a semiconductor film on a substrate.

2. The multi-chamber assembly according to claim 1, further comprising a motorized mechanical system comprising at least one inter-chamber actuator adapted to grab and displace the removable reaction unit from the first chamber to the second chamber, and/or vice versa, through the transfer device.

3. The multi-chamber assembly according to claim 1, wherein the transfer device comprises at least one transfer aperture and at least one transfer gate valve adapted to open and close said at least one transfer aperture.

4. The multi-chamber assembly according to claim 1, wherein the transfer device comprises:
an enclosed interspace between the first chamber and second chamber; and
at least one first transfer aperture, connecting the interspace with the first chamber; and
at least one second transfer aperture, connecting the interspace with the second chamber and facing the at least one first transfer aperture; and
at least one transfer gate valve adapted to seal the first and/or second transfer apertures.

5. The multi-chamber assembly according to claim 4, wherein the at least one first transfer aperture and the at least one second transfer aperture are each equipped with a transfer gate valve; and the transfer device comprising at least one automated double sealing system adapted to operate each of said transfer gate valves independently from each other.

6. The multi-chamber assembly according to claim 1, wherein the second chamber is provided with at least one shelf adapted to support at least one removable reaction unit; and the second chamber further comprising a single-chamber automated system configured to displace at least one removable reaction unit within the second chamber, and optionally through the resealable access.

7. The multi-chamber assembly according to claim 1, further comprising a heating system configured to heat the second chamber to a temperature of 150-500° C.

8. The multi-chamber assembly according to claim 7, wherein the heating system is an electrical resistance heating system.

9. The multi-chamber assembly according to claim 1, further comprising a vacuum system configured to create a vacuum of less than 10 mbar in the second chamber.

10. The multi-chamber assembly according to claim 9, wherein the vacuum system is configured to create a vacuum of less than 1 mbar, preferably less than 10⁻³ mbar.

11. The multi-chamber assembly according to claim 1, wherein the second chamber is further provided with at least one gas inlet and at least one gas outlet.

12. The multi-chamber assembly according to claim 2, wherein the motorized mechanical system comprises a linear actuator provided with an end effector.

13. The multi-chamber assembly according to claim 1, wherein:
the first chamber comprises a substrate transfer aperture adapted to transfer a substrate holder supporting a substrate; and
the multi-chamber assembly further comprises a third chamber placed in communication with the first chamber through the substrate transfer aperture; and
the third chamber is adapted to receive or discharge the substrate holder from/to the first chamber through the substrate transfer aperture via motorized or manual means.

14. A reactor assembly for displacing and handling a reaction unit for preventive maintenance operations comprising:
a reactor for epitaxial deposition of a semiconductor film on a substrate, comprising a reaction chamber having a reaction unit removable in one piece from a susceptive casing;
a multi-chamber assembly according to claim 1;
an automated handling machine for handling the reaction unit;
wherein the reactor extends along a longitudinal direction, and the automated handling machine is provided with a selective handling assembly comprising:
a first end effector adapted to mechanically couple with the reaction unit to displace it along the longitudinal direction;
a second end effector adapted to mechanically couple with a substrate holder to displace it along the longitudinal direction;
wherein the selective handling assembly comprises at least a first actuator adapted to displace the first and second end effector in the longitudinal direction from an extended position to a retreated position, and vice versa; the second end effector being adapted to withdraw, or insert, the substrate holder from, or into, the removable reaction unit; and the first end effector being adapted to withdraw, or insert, the reaction unit from, or into, the reactor.
